(19) United States
(12) Patent Application Publication
(10) Pub. No.: US 2026/0036644 A1
(43) Pub. Date: Feb. 5, 2026

(54) TEST DEVICE FOR MODULAR MULTI-LEVEL CONVERTER

(71) Applicant: HONGIK UNIVERSITY INDUSTRY-ACADEMIA COOPERATION FOUNDATION, Seoul (KR)

(72) Inventors: Dong-Myung LEE, Yongin-si (KR); Sang-Jin HWANG, Gimpo-si (KR)

(73) Assignee: HONGIK UNIVERSITY INDUSTRY-ACADEMIA COOPERATION FOUNDATION, Seoul (KR)

(21) Appl. No.: 19/257,835

(22) Filed: Jul. 2, 2025

(30) Foreign Application Priority Data
Aug. 1, 2024 (KR) 10-2024-0102744

(51) Int. Cl. G01R 31/40

(52) U.S. Cl. CPC G01R 31/40

(57) ABSTRACT

Disclosed is a test device to test the operation of an MMC by fabricating only one or several SMs constituting the MMC testing under real-time operating conditions. The test device for a modular multi-level converter (MMC) includes a simulation model of an MMC having at least one arm to which sub modules (SMs) are serially connected, at least one test target SM among the serially connected SMs being replaced with a dependent voltage source; an arm current simulation circuit including an equivalent SM that implements the test target SM as actual physical hardware and an inverter that supplies current to the equivalent SM; and a control unit configured to control the arm current simulation circuit to correspond to an operation of the simulation model and set a voltage corresponding to a charge/discharge voltage of the equivalent SM of the arm current simulation circuit to the dependent voltage source.

### TECHNICAL FIELD

This application is based on and claims priority from Korean Patent Application No. 10-2024-0102744, filed on Aug. 1, 2024, with the Korean Intellectual Property Office, the disclosure of which is incorporated herein in its entirety by reference.

The present disclosure relates to a modular multi-level converter (MMC), and more specifically, to a test device for a modular multi-level converter.

### BACKGROUND ART

The application of modular multi-level converters (MMCs) (hereinafter, MMC) is expanding to high-voltage application circuits. MMC is a power converter in which sub-modules (hereinafter, SMs) in the form of half bridges or full bridges are connected in series to generate a multi-level voltage. The application areas are high-voltage direct current transmission such as HVDC (High Voltage Direct Current) and high-voltage motor driving. Since MMC includes tens to thousands of identical SMs depending on the voltage level, there is a problem that it takes a lot of cost and time to manufacture the entire system of MMC and test its operation or algorithm. For example, when using a 20-voltage level structure for grid connection of a wind power plant, 120 SMs are required for a 3-phase MMC. When developing an MMC, if a design error or correction of an SM is necessary during testing for the entire system, there is a difficulty in that all 120 SMs must be corrected.

### DISCLOSURE

### Technical Problem

Therefore, if the overall operation of an MMC can be tested using one SM or several SMs, it will lead to a significant reduction in the MMC development period and cost. Accordingly, the present disclosure is directed to providing a test device that tests the operation of the entire system of an MMC by testing one SM among a plurality of SMs constituting the MMC under real-time operating conditions using a real-time implementation system, which is HILS (hardware in the loop simulation), and an arm current simulation circuit.

### Technical Solution

In one aspect, there is provided a test device for a modular multi-level converter (MMC), comprising: a simulation model of an MMC having at least one arm to which sub modules (SMs) are serially connected, at least one test target SM among the serially connected SMs being replaced with a dependent voltage source; an arm current simulation circuit including an equivalent SM that implements the test target SM as actual physical hardware and an inverter that supplies current to the equivalent SM; and a control unit configured to control the arm current simulation circuit to correspond to an operation of the simulation model and set a voltage corresponding to a charge/discharge voltage of the equivalent SM of the arm current simulation circuit to the dependent voltage source.

The control unit may be configured to control the inverter so that the same arm current as the arm current supplied to the test target SM of the simulation model is supplied to the equivalent SM.

The control unit may include an inverter control module configured to control the inverter, and the inverter control module may include a current comparator configured to compare an arm current command value applied to the simulation model with an inductor current of the arm current simulation circuit and output an error between the arm current command value and the inductor current; a current controller configured to output a control signal based on the error; a PWM (Pulse Width Modulation) generator configured to compare a carrier waveform with the control signal to generate a PWM signal and apply the PWM signal to a gate of a first switch of the inverter; and an inverting circuit configured to invert the PWM signal and apply the inverted PWM signal to a gate of a second switch of the inverter.

The current comparator may be a proportional integral (PI) controller.

The control unit may be configured to supply a gate signal corresponding to an operation of the test target SM of the simulation model to the equivalent SM and set the voltage corresponding to the charge/discharge voltage of the equivalent SM to the dependent voltage source.

The simulation model may be implemented with HILS (Hardware In the Loop Simulation).

### Advantageous Effects

According to the present disclosure, by manufacturing only one or several SMs (Sub Modules) that constitute the MMC entire system and testing the operation of the MMC entire system, the conventional problem that the entire SMs must be corrected when a SM design error or correction is necessary is solved, and the development cost and time of the MMC entire system may be drastically reduced.

### DESCRIPTION OF DRAWINGS

FIG. 1 is a drawing showing a three-phase MMC according to an embodiment of the present disclosure.

FIG. 2 is a drawing showing the configuration of a test device according to an embodiment of the present disclosure.

FIG. 3 is a drawing showing an arm current direction for a test target SM and the change in voltage magnitude of capacitor of the test target SM according to a gate signal before replacing the simulation model of FIG. 2 with a dependent voltage source.

FIG. 4 is a drawing showing a charge/discharge path according to a gate state of two switches in an equivalent SM when controlling the arm current (i_{SM}) using an inverter in the arm current simulation circuit of FIG. 2.

FIG. 5 is a diagram showing the configuration of an inverter control module for controlling the inverter according to an embodiment of the present disclosure.

FIG. 6 is a diagram showing the configuration of a full bridge type inverter of the arm current simulation circuit according to an embodiment of the present disclosure.

FIG. 7 is a graph comparing voltage waveforms of capacitors of the SM of the simulation model and the arm current simulation circuit according to an embodiment of the present disclosure.

FIG. 8 is a graph comparing waveforms of arm currents of the simulation model and the arm current simulation circuit according to an embodiment of the present disclosure.

### BEST MODE

Hereinafter, preferred embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation. Therefore, the description proposed herein is just a preferable example for the purpose of illustrations only, not intended to limit the scope of the disclosure, so it should be understood that other equivalents and modifications could be made thereto without departing from the scope of the disclosure.

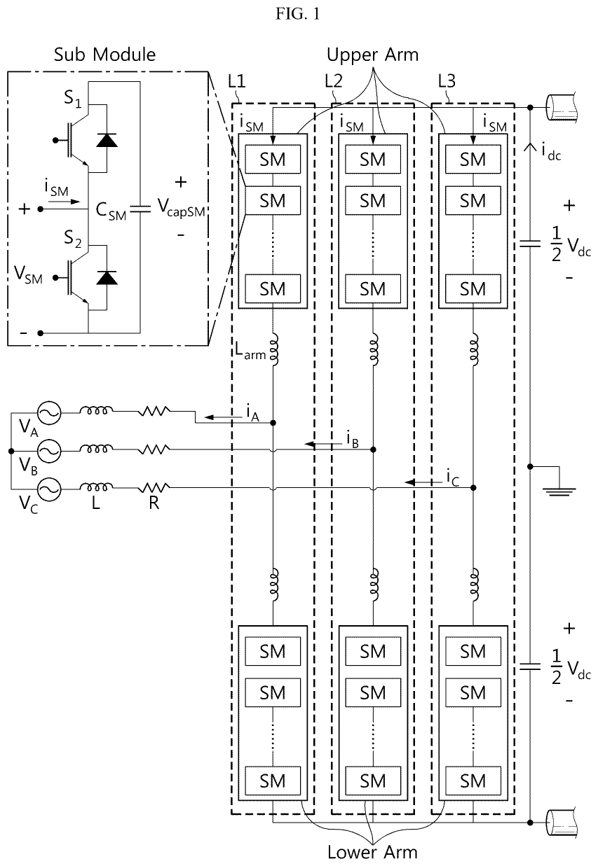

FIG. 1 is a drawing showing a three-phase MMC according to an embodiment of the present disclosure. As shown in FIG. 1, the three-phase MMC has three legs L1, L2, L3 according to the phase, and each leg L1, L2, L3 has an upper arm and a lower arm. Each of the upper arm and the lower arm has a plurality of SMs (Sub Modules) connected in series to convert the input DC power into three-phase AC power. The SM of FIG. 1 is a half bridge type, but may be a full bridge type. The half bridge type SM includes a capacitor (C_{SM}) and two transistors (e.g., IGBTs (Insulated Gate Bipolar Transistors)). For example, if a 20-voltage level structure is used when connecting a wind power plant to the grid, 120 SMs are required for the three phases in total. When developing an MMC, if a design error or correction of an SM is necessary during testing for the entire system, there is a difficulty in that all 120 SMs must be corrected. Therefore, if a method of developing and testing an algorithm for the entire system by fabricating only one or several SMs is applied during the development phase, it is possible to drastically reduce the system development cost and time.

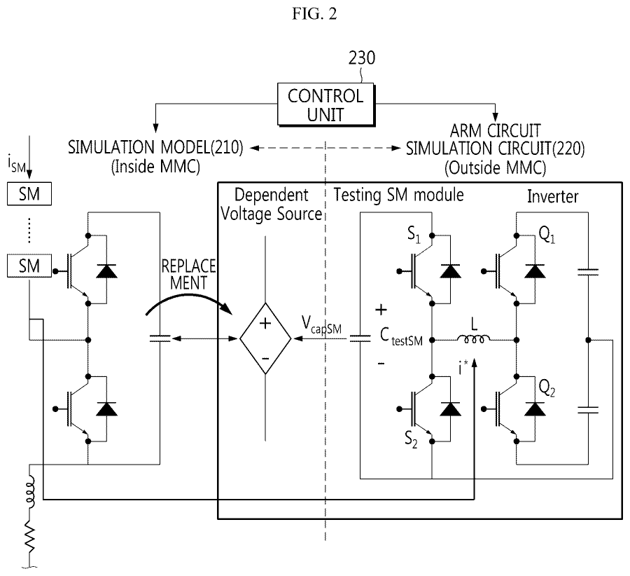

FIG. 2 is a drawing showing the configuration of a test device according to an embodiment of the present disclosure. Referring to FIG. 2, the test device according to this embodiment includes a simulation model (Inside MMC) 210, an arm current simulation circuit (Outside MMC) 220, and a control unit 230. Here, the simulation model 210 is an MMC implemented as software of HILS (Hardware In the Loop Simulation), which is a real-time implementation system, and a part of some arms of the MMC is shown in FIG. 2. For example, the simulation model 210 may be a three-phase MMC of FIG. 1. The arm current simulation circuit 220 is physical hardware. The control unit 230 may be connected to the simulation model 210 and the arm current simulation circuit 220 to control each of the simulation model 210 and the arm current simulation circuit 220.

As shown in FIG. 2, the simulation model 210 includes SMs expressed as half bridges that are connected in series, and among them, one test target SM is replaced with a dependent voltage source. The arm current simulation circuit 220 includes an SM (Testing SM module in FIG. 2) that implements the test target SM as actual physical hardware and an inverter that supplies an arm current to the SM. For reference, one SM to be tested in the simulation model 210 is called a test target SM, and an SM included in the arm current simulation circuit 220 is called an equivalent SM because it implements the test target SM as actual physical hardware. Although this embodiment is described as testing one SM, it is obvious that more than one SM can be tested.

The voltage magnitude of the dependent voltage source is determined by the gate signal for the equivalent SM implemented in the arm current simulation circuit 220 and the capacitor voltage magnitude of the equivalent SM. That is, the voltage magnitude of the dependent voltage source is expressed by the following formula. S represents the gate signal, and has a value of 1 when the upper switch (S1) of the equivalent SM is ON, and a value of 0 when the lower switch (S2) is ON. The magnitude of V_{capSM} is an actual voltage of the capacitor (C_{testSM}) in the SM drawn on the right in FIG. 2. In FIG. 2, the voltage is shown as being transferred from the capacitor (C_{testSM}) in the SM of the arm current simulation circuit 220 to the dependent voltage source of the simulation model 210, but this is just for understanding, and the voltage of the capacitor (C_{testSM}) in the SM of the arm current simulation circuit 220 is measured by the control unit 230, and the control unit 230 sets the voltage magnitude of the dependent voltage source of the simulation model 210.

$$Magnitude of dependent voltage source = S \times {V}_{capSM}$$

The voltage of the SMs of each arm in the MMC implemented with the simulation model 210 is determined by the arm current (i_{SM}) of the MMC and the gate signal (S) for two switches of each SM. Correspondingly, the same arm current (i_{SM}) and the same gate signal (S) are applied to the arm current simulation circuit 220. Specifically, the control unit 230 controls the inverter so that the same arm current (i_{SM}) as the arm current (i_{SM}) in the MMC implemented with the simulation model 210 flows in the arm current simulation circuit 220, and applies the same gate signal (S) as the gate signal (S) supplied in the MMC implemented with the simulation model 210 to the two switches (S₁, S₂) of the equivalent SM of the arm current simulation circuit 220.

The inverter of FIG. 2 is a half-bridge type inverter. The inverter converts DC power into AC power and outputs the AC power under the control of the control unit 230. The inverter of FIG. 2 includes two switches (Q₁, Q₂), and the magnitude and direction of the current flowing through the inductor L are controlled by the complementary operation of the two switches (Q₁, Q₂). The control unit 230 controls the two switches (Q₁, Q₂) of the inverter so that the same current identical as the arm current (i_{SM}) of the MMC implemented by the simulation model 210 flows through the inductor L.

If the arm current (i_{SM}) and the gate signal (S) are applied to the equivalent SM of the arm current simulation circuit 220, the voltage of the capacitor (C_{testSM}) in the equivalent SM performs charging or discharging depending on the value of the gate signal (i.e., 1 for the upper switch (S₁) or the lower switch (S₂)) and the direction of the arm current (i_{SM}). Accordingly, the magnitude of V_{capSM}, i.e., the voltage of the capacitor (C_{testSM}) existing in the equivalent SM changes. According to the voltage of the capacitor (C_{testSM}) that changes according to the actual operating conditions, that is, according to Equation (1), the control unit 230 sets the corresponding voltage to the dependent voltage source using the simulation model 210, and the simulation model 210 verifies the operation as an MMC.

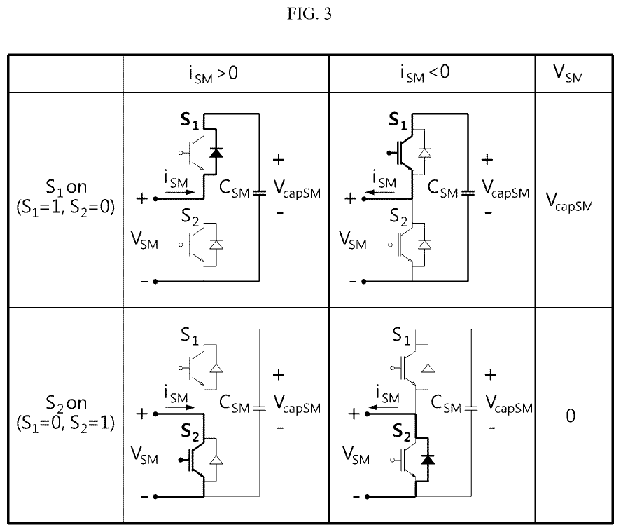

FIG. 3 is a drawing showing an arm current direction for a test target SM and the change in voltage magnitude of capacitor of the test target SM according to a gate signal before replacing the simulation model 210 of FIG. 2 with a dependent voltage source. As shown in FIG. 3, if the lower switch (S₂) in the test target SM is ON, there is no voltage change in the capacitor (C_{SM}) regardless of the direction of the arm current (i_{SM}). That is, there is no charge/discharge path to V_{capSM}. In contrast, if the upper switch (S₁) in the test target SM is ON and the arm current (i_{SM}) is positive, charging occurs to the capacitor (C_{SM}) of the test target SM, thus increasing V_{capSM}, and if the arm current (i_{SM}) is negative, discharging occurs in the capacitor (CSM) of the test target SM, thus decreasing V_{capSM}.

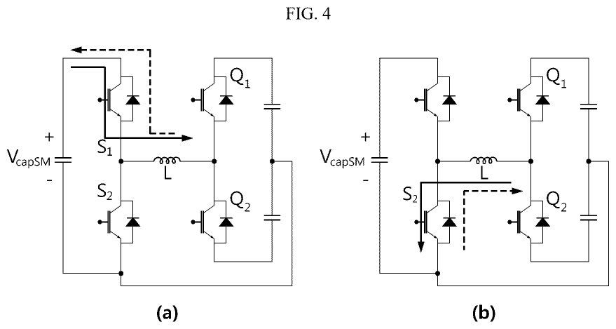

FIG. 4 is a drawing showing a charge/discharge path according to a gate state of two switches in an equivalent SM when controlling the arm current (i_{SM}) using an inverter in the arm current simulation circuit 220 of FIG. 2. (a) of FIG. 4 shows the current path according to the load current direction when the upper switch (S₁) in the equivalent SM of the arm current simulation circuit 220 is ON. It may be found that the same current path as the case where the gate signal (S) of the upper switch (S₁) is 1 in the test target SM of the simulation model 210 of FIG. 3 is generated. It may be found that the current control by the inverter and the change in the V_{capSM} value have the same form. (b) of FIG. 4 shows the current path when the lower switch (S₂) in the equivalent SM of the arm current simulation circuit 220 is ON. It may be found that there is no current path to V_{capSM}, which is the same as the case where the gate signal (S) of the lower switch (S₂) is 1 in the test target SM of the simulation model 210 of FIG. 3, and thus there is no change in the V_{capSM} magnitude. Since the arm current is simulated identically to the actual arm current (i_{SM}) using the inverter in the arm current simulation circuit 220, it may be found that the voltage magnitude of V_{capSM} is implemented identically to the actual usage conditions.

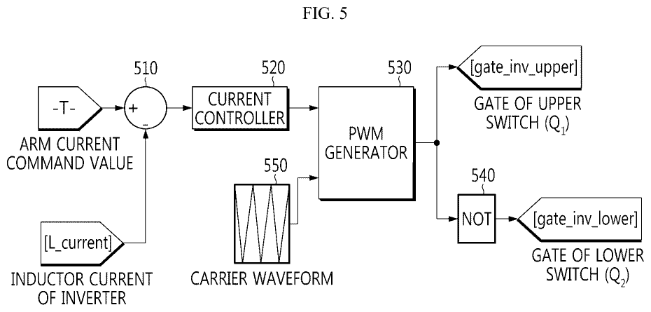

FIG. 5 is a diagram showing the configuration of an inverter control module for controlling the inverter according to an embodiment of the present disclosure, and the inverter control module is included in the control unit 230. As shown in FIG. 5, the inverter control module includes a current comparator 510, a current controller 520, a PWM generator 530, and an inverting circuit 540.

The current comparator 510 receives the arm current command value applied to the simulation model 210 and the current of the inductor L of the arm current simulation circuit 220, compares the arm current command value with the current of the inductor L, and outputs an error between the arm current command value and the current of the inductor L to the current controller 520.

The current controller 520 outputs a control signal based on the error received from the current comparator 510. Preferably, the current controller 520 may be a proportional integral (PI) controller. The proportional integral controller integrates the error signal to generate a control signal. The proportional integral controller outputs a control signal so that the output value becomes a target value, where the output value may be the current of the inductor L and the target value may be the arm current command value.

The PWM generator 530 compares the control signal output from the current controller 520 with a carrier waveform 550 to generate a PWM (Pulse Width Modulation) signal. The PWM signal generated by the PWM generator 530 is divided into two branches, where the PWM signal of the first branch is input to the gate of the upper switch (Q₁) of the inverter, and the PWM signal of the second branch is taken as Not through the inverting circuit 540, that is, inverted, and input to the gate of the lower switch (Q₂) of the inverter. For example, if 1 is input to the upper switch (Q₁), 0 is input to the lower switch (Q₂). Accordingly, the arm current generated from the inverter becomes identical to the arm current command value applied to the simulation model 210.

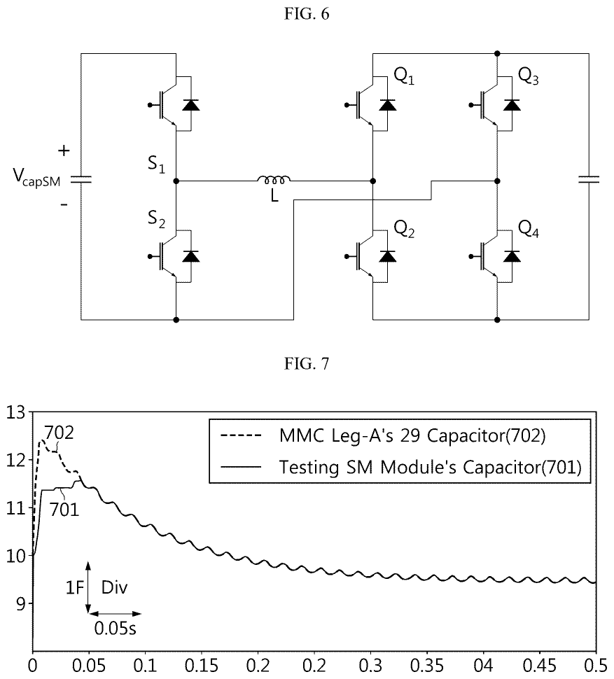

FIG. 6 is a diagram showing the configuration of a full bridge type inverter of the arm current simulation circuit according to an embodiment of the present disclosure. The inverter of the arm current simulation circuit 220 of the former embodiments is a half bridge type. As shown in FIG. 6, the inverter of the arm current simulation circuit 220 may be implemented in a full bridge type instead of a half bridge type. While the half bridge type inverter includes two switches (Q₁, Q₂), the full bridge type inverter includes four switches (Q₁, Q₂, Q₃, Q₄). The AC voltage output of the inverter is generated from the contact between the first switch (Q₁) and the third switch (Q₃) and the contact between the second switch (Q₂) and the fourth switch (Q₄). The control unit 230 may generate the AC voltage output by controlling the switching of the first switch pair (Q₁ and Q₄) and the second switch pair (Q₂ and Q₃) not to overlap each other.

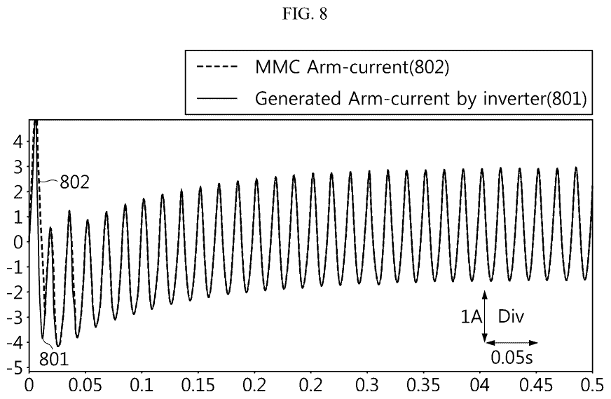

FIG. 7 is a graph comparing voltage waveforms of capacitors of the SM of the simulation model and the arm current simulation circuit according to an embodiment of the present disclosure. Reference sign 701 represents the voltage waveform of the capacitor of the equivalent SM of the arm current simulation circuit 220, and reference sign 702 represents the voltage waveform of the capacitor of the remaining individual SMs in the arms of the simulation model 210 except for the dependent voltage source. The waveform up to 0.5 second is enlarged to show the detailed waveform. In this embodiment, 30 SMs are included in each arm of the simulation model 210, and therefore reference sign 702 represents the voltage waveform of a total of 29 SMs. As shown in FIG. 7, it may be found that the capacitor voltages of the SMs inside the simulation model 210 and the capacitor voltage waveform of the equivalent SM inside the arm current simulation circuit 220 have the same shape after the initial time, that is, the current build-up time of the inverter. That is, the validity of the test of the present disclosure may be confirmed.

FIG. 8 is a graph comparing waveforms of arm currents of the simulation model and the arm current simulation circuit according to an embodiment of the present disclosure. Reference sign 801 represents the arm current waveform of the arm current simulation circuit 220, and reference sign 802 represents the arm current waveform of the simulation model 210. The waveform up to 0.5 second is enlarged to show the detailed waveform. As shown in FIG. 8, it may be found that the waveforms of the arm current in the simulation model 210 and the arm current in the arm current simulation circuit 220 show the same shape after the initial time, that is, the current build-up time of the inverter. That is, the validity of the test of the present disclosure may be confirmed.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

What is claimed is:

1. A test device for a modular multi-level converter (MMC), comprising:
a simulation model of an MMC having at least one arm to which sub modules (SMs) are serially connected, at least one test target SM among the serially connected SMs being replaced with a dependent voltage source;
an arm current simulation circuit including an equivalent SM that implements the test target SM as actual physical hardware and an inverter that supplies current to the equivalent SM; and
a control unit configured to control the arm current simulation circuit to correspond to an operation of the simulation model and set a voltage corresponding to a charge/discharge voltage of the equivalent SM of the arm current simulation circuit to the dependent voltage source.

2. The test device according to claim 1,
wherein the control unit is configured to control the inverter so that the same arm current as the arm current supplied to the test target SM of the simulation model is supplied to the equivalent SM.

3. The test device according to claim 2,
wherein the control unit includes an inverter control module configured to control the inverter, and
wherein the inverter control module includes:
a current comparator configured to compare an arm current command value applied to the simulation model with an inductor current of the arm current simulation circuit and output an error between the arm current command value and the inductor current;
a current controller configured to output a control signal based on the error;
a PWM (Pulse Width Modulation) generator configured to compare a carrier waveform with the control signal to generate a PWM signal and apply the PWM signal to a gate of a first switch of the inverter; and
an inverting circuit configured to invert the PWM signal and apply the inverted PWM signal to a gate of a second switch of the inverter.

4. The test device according to claim 3,
wherein the current comparator is a proportional integral (PI) controller.

5. The test device according to claim 1,
wherein the control unit is configured to supply a gate signal corresponding to an operation of the test target SM of the simulation model to the equivalent SM and set the voltage corresponding to the charge/discharge voltage of the equivalent SM to the dependent voltage source.

6. The test device according to claim 1,
wherein the simulation model is implemented with HILS (Hardware In the Loop Simulation).
